(19) United States
(12) Patent Application Publication
(10) Pub. No.: US 2002/0004295 A1
(43) Pub. Date: Jan. 10, 2002

(54) Manufacturing method of head chip

(76) Inventor: Toshihiko Harajiri, Chiba-shi (JP)

Correspondence Address: ADAMS & WILKS, 31st FLOOR, 50 BROADWAY, NEW YORK, NY, 10004, US

(21) Appl. No.: 09/864,938

(22) Filed: May 24, 2001

(30) Foreign Application Priority Data
May 26, 2000 (JP) 2000-155782

(51) Int. Cl. H01L 21/4763

(52) U.S. Cl. 438/586

(57) ABSTRACT

A manufacturing method of a head chip is provided by which manufacturing cost is reduced and manufacturing steps are simplified. In a method of manufacturing a head chip, in which partition walls 12 made of piezoelectric ceramic are arranged in a predetermined interval between a first upper board 11 and a second lower board 16, which are made of a dielectric material; chambers are defined among the respective partition walls 12; and a wiring line 15 is provided on a surface of any one of the first board 11 and the second board 16, and is electrically conducted to an electrode 14 formed on a side surface of the partition wall 12, and also is elongated up to an outer side of an edge portion of the partition wall 12 along a longitudinal direction, the manufacturing method comprises a step in which the electrode 14 and a metal film 15a which constitutes a portion of the wiring line 15 are formed by way of selective electroless plating, and these electrode 14 and wiring line 15 are electrically conducted to each other.

### BACKGROUND OF THE INVENTION

1. Field of the invention

The present invention relates to a method for manufacturing a head chip which is mounted on an ink-jet type recording apparatus applicable to, for example, a printer and a facsimile.

2. Description of the Related Art

Conventionally, an ink-jet type recording apparatus is known in the technical field, in which a recording head for jetting ink droplets from a plurality of nozzles is employed to record characters and/or images on a recording medium. In such an ink-jet type recording apparatus, the recording head positioned opposite to the recording medium is provided on a head holder, and this head holder is mounted on a carriage so as to be scanned along a direction perpendicular to a transport direction of the recording medium.

In FIG. 12, there is shown an exploded/perspective view of one example of such a recording head. FIGS. 13A and 13B are sectional view of a major portion of this recording head. FIG. 13A is a sectional view of the recording head taken along the longitudinal direction of side walls. FIG.13B is a sectional view of the recording head taken along the thickness direction of side walls. A plurality of grooves 102 are arranged in a piezoelectric ceramic plate 101 in a parallel manner. The respective grooves 102 are separated from each other by side walls 103. One edge portion of each of the grooves 102 in the longitudinal direction is elongated up to one edge surface of the piezoelectric ceramic plate 101, whereas the other edge portion is not elongated up to the other edge surface of this piezoelectric ceramic plate, and a depth thereof gradually becomes shallow. Also, an electrode 105 used to apply a driving electric field is formed on surfaces of both the side walls 103 on the opening side within each of the grooves 102 along the longitudinal direction.

A cover plate 107 is jointed via an adhesive agent 109 to the grooves 102 of the piezoelectric ceramic plate 101 on the opening side. This cover plate 107 has an ink chamber 111 that constitutes a concave portion which is communicated to the shallow other edge portion of each of the grooves 102 and an ink supply port 112 that is penetrated through a bottom portion of this ink chamber 111 along a direction opposite to the direction of the grooves 102.

A nozzle plate 115 is jointed on an edge surface of a joint member made by the piezoelectric ceramic plate 101 and the cover plate 107, at which the grooves 102 are opened. Nozzle openings 117 are formed in the nozzle plate 115 at such positions located opposite to the respective grooves 102.

It should be noted that a wiring board 120 is fixed on such a surface of the piezoelectric ceramic plate 101, which is located opposite to the nozzle plate 115 and also opposite to the cover plate 107. A wiring line 122 which is electrically connected to each of the electrodes 105 by employing a bonding wire 121 or the like is formed on the wiring board 120. A driver voltage may be applied via this wiring line 122 to the electrode 105.

In the recording head constituted in this manner, when ink is filled from the ink supply port 112 into the respective grooves 102 and a predetermined driving electric field is applied via the electrode 105 to the side walls 103 on both sides of a predetermined groove 102, the side walls 103 are deformed, so that a capacity formed within this predetermined groove 102 is change As a result, the ink filled inside the grooves 102 may be jetted from the nozzle opening 117.

For example, as shown in FIG. 14, in the case where ink is jetted from a nozzle opening 117 corresponding to a groove 102a, a positive driving voltage is applied to both electrodes 105a and 105b provided in the groove 102a, and also electrodes 105c and 105d located opposite to these electrodes 105a and 105b are grounded. As a consequence, a driving electric field directed to the groove 102a is effected to the side walls 103a and 103b. When this driving electric field is positioned perpendicular to the polarization direction of the piezoelectric ceramic plate 101, both the side walls 103a and 103b are deformed along the direction of the groove 102a due to the piezoelectric thickness slip effect, so that the capacity defined inside the groove 102a is reduced to there by increase pressure. Thus, the ink may be jetted from the nozzle opening 117.

However, since such a head chip employs a large amount of high-cost ceramic, there is a problem in that the manufacturing cost of the head chip is high.

To solve such a problem, Japanese Patent Examined Publication No. Hei 6-6375 has proposed such a head chip which is manufactured by the plate-shaped board made of glass, piezoelectric ceramic plate made by arranging the pressure chambers in the array form on this plate-shaped board, and ink chamber plate made of glass.

In accordance with this head chip, since both the plate-shaped board and the ink chamber plate are made of low-cost glass materials, this head chip can be manufactured in low cost and also the manufacturing time can be shortened.

However, the above-explained head chip with employment of the glass board owns such a problem in that since the electrode for applying the voltage to the piezoelectric ceramic plate has to be formed by way of the oblique vapor deposition, the manufacturing cost is increased.

Also, when the wiring lines electrically conducted to this electrode are extracted, these wiring lines are processed by metal plating such as nickel plating or gold plating, and thereafter the metal plated-wiring lines has to be cut one by one by using a laser. Thus, there is another problem in that the process step becomes cumbersome, and the manufacturing cost is increased.

Furthermore, even when the wiring lines are directly formed on the glass board by way of the metal plating, there is another problem in that the fitting characteristic is deteriorated, and thus, the formed wiring lines may readily peel off from the glass board.

### SUMMARY OF THE INVENTION

The present invention has been made to solve such problems, and therefore, has an object to provide a method of manufacturing a head chip, while manufacturing cost is reduced, and also a manufacturing step is simplified.

In order to solve the above problems, according to a first aspect of the present invention, there is provided a method of manufacturing a head chip, in which partition walls made of piezoelectric ceramic are arranged in a predetermined interval between a first upper board and a second lower board, which are made of a dielectric material; chambers are defined among the respective partition walls; and a wiring line is provided on a surface of any one of the first board and the second board, and is electrically conducted to an electrode formed on a side surface of the partition wall, and also is elongated up to an outer side of an edge portion of the partition wall along a longitudinal direction; the manufacturing method characterized by comprising:

a step in which the electrode and a metal film which constitutes a portion of the wiring line are formed by way of selective electroless plating, and these electrode and wiring line are electrically conducted to each other.

According to a second aspect of the present invention, in the first aspect of the present invention, there is provided a manufacturing method of a head chip characterized in that:

at least in a region corresponding to the chamber, the inorganic conductive film is formed on a portion located opposite to both edge portions of the partition wall in a width direction such that one side surface of the inorganic conductive film is exposed a long a longitudinal direction of the partition wall; and

the electrode is electrically conducted to at least the one side surface of the inorganic conductive film, which is exposed.

According to a third aspect of the present invention, in the second aspect of the present invention, there is provided a manufacturing method of a head chip characterized in that:

the electrode is formed byway of selective electroless plating such that the electrode is made in contact with the exposed one side surface of the inorganic conductive film to thereby be electrically conducted to the inorganic conductive film; and also the metal film is formed on the inorganic conductive film of the outer side of the partition wall along the longitudinal direction, whereby the electrode is electrically and mutually conducted via the inorganic conductive film to the metal film.

According to a fourth aspect of the present invention, in any one of the first to third aspects of the present invention, there is provided a manufacturing method of a head chip, characterized by further comprising, prior to the step of forming the electrode and the metal film:

a step of forming an inorganic conductive film having a predetermined shape, which constitutes a portion of the wiring line, on any one of the first board and the second board; and

a step of providing the partition wall on the one board where the inorganic conductive film is formed.

According to a fifth aspect of the present invention, in any one of the first to third aspects of the present invention, there is provided a manufacturing method of a head chip characterized in that:

the step for forming the partition wall includes:

a step of joining a piezoelectric ceramic plate corresponding to a block which constitutes a plurality of partition walls on any one of the first board and the second board; and

a step of cutting the piezoelectric ceramic plate to form a plurality of partition walls.

According to a sixth aspect of the present invention, in the fifth aspect of the present invention, there is provided a manufacturing method of a head chip characterized in that:

the piezoelectric ceramic plate is jointed on the one board where the inorganic conductive film is formed, and both the piezoelectric ceramic plate and the one board located up to a portion of the one board in the thickness direction are removed, whereby the plurality of portion walls are formed.

According to a seventh aspect of the present invention, in any one of the first to third aspects of the present invention, there is provided a manufacturing method of a head chip characterized in that:

the dielectric material is glass.

According to a eighth aspect of the present invention, in any one of the first to third aspects of the present invention, there is provided a manufacturing method of a head chip characterized in that:

the inorganic conductive film is made of at least one sort of material selected from the group consisting of ITO, Sn, 02, ZnO, and ATO.

According to a ninth aspect of the present invention, in any one of the first to third aspects of the present invention, there is provided a manufacturing method of a head chip characterized in that:

a thickness of the inorganic conductive film is set to be equal to or thinner than 3 μm.

According to a tenth aspect of the present invention, in any one of the first to third aspects of the present invention, there is provided a manufacturing method of a head chip characterized in that:

the partition wall is formed by adhering two members, which have different polarization, to each other.

According to a eleventh aspect of the present invention, in any one of the first to third aspects of the present invention, there is provided a manufacturing method of a head chip characterized in that:

both the electrode and the metal film are made of at least one material selected from nickel and gold.

According to a twelfth aspect of the present invention, in any one of the first to third aspects of the present invention, there is provided a manufacturing method of ahead chip, characterized by further comprising a step of providing a nozzle plate on one opening end of the chamber along a longitudinal direction of the partition wall, the nozzle plate having nozzle openings which are communicated to the respective chambers.

According to a thirteenth aspect of the present invention, in the twelfth aspect of the present invention, there is provided a manufacturing method of a head chip characterized in that:

the nozzle plate is made of a dielectric material.

In accordance with the manufacturing method of the present invention, while the board made of the dielectric material is employed, the inorganic conductive film, that has the better fitting characteristic with the dielectric material, is provided at the lowermost layer of the wiring line. As a consequence, the manufacturing step can be made simple, and also the manufacturing cost can be reduced. Moreover, the wiring lines can be easily and firmly conducted to the electrodes.

### BRIEF DESCRIPTION OF THE DRAWINGS

In the accompanying drawings:

FIG. 1 is a perspective view showing a head chip according to an embodiment of the present invention;

FIG. 2 is a perspective/sectional view indicating the head chip according to the embodiment of the present invention;

FIG. 3 is a sectional view representing the head chip according to the embodiment of the present invention, taken along a parallel-arranging direction of this head chip, and also a sectional view of the head chip, taken along a line A-A′ thereof;

FIG. 4 is a top view showing a manufacturing method of the head chip according to the embodiment of the present invention;

FIG. 5 is a sectional view representing the head chip corresponding to the respective manufacturing steps of FIG. 5 along the parallel-arranging direction of the chamber;

FIG. 6 is a top view showing a manufacturing method of the head chip according to the embodiment of the present invention;

FIG. 7 is a sectional view representing the head chip corresponding to the respective manufacturing steps of FIG. 7 along the parallel-arranging direction of the chamber;

FIG. 8 is a sectional view showing another example of an inorganic conductive film according to the present invention, along a longitudinal direction of the chamber;

FIG. 9 is a perspective view indicating an assembly of a unit with employment of the head chip according to one embodiment of the present invention;

FIG. 10 is a perspective view indicating an assembly of a unit with employment of the head chip according to one embodiment of the present invention;

FIG. 11 is a perspective view showing a use mode of the unit with employment of the head chip according to one embodiment of the present invention;

FIG. 12 is an exploded/perspective view schematically indicating a recording head in accordance with a conventional technique;

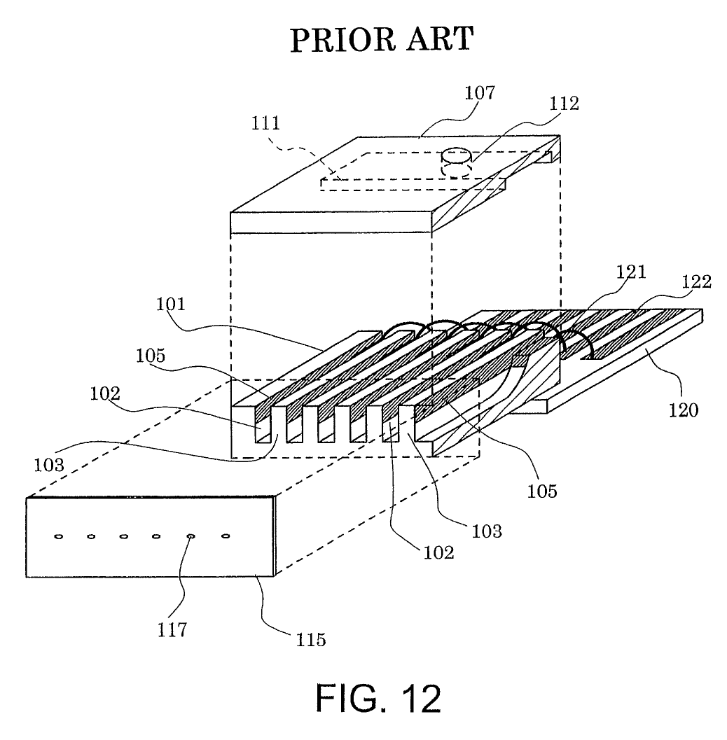

FIG. 13 is a sectional view schematically indicating the recording head in accordance with the conventional technique; and

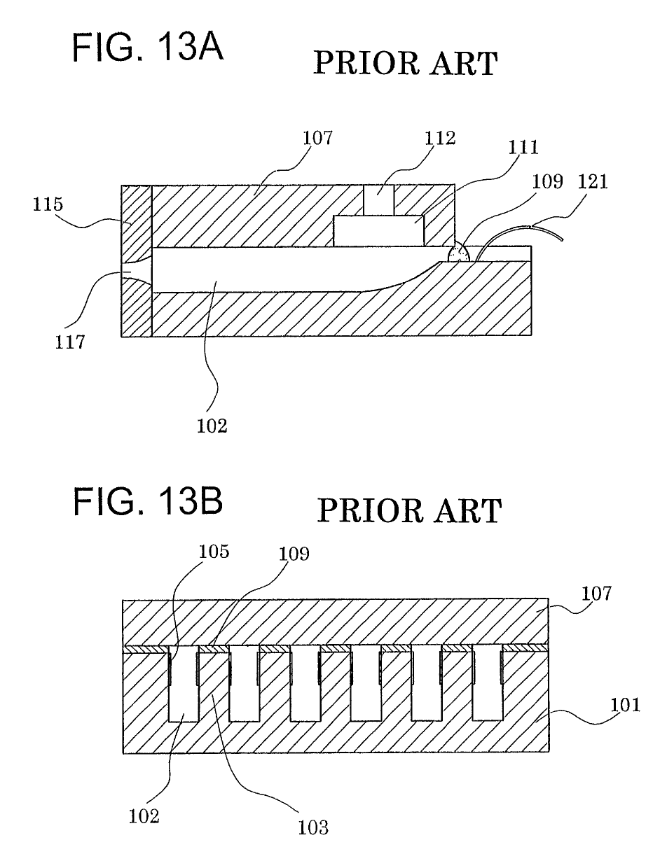

FIG. 14 is a sectional view schematically indicating the recording head in accordance with the conventional technique.

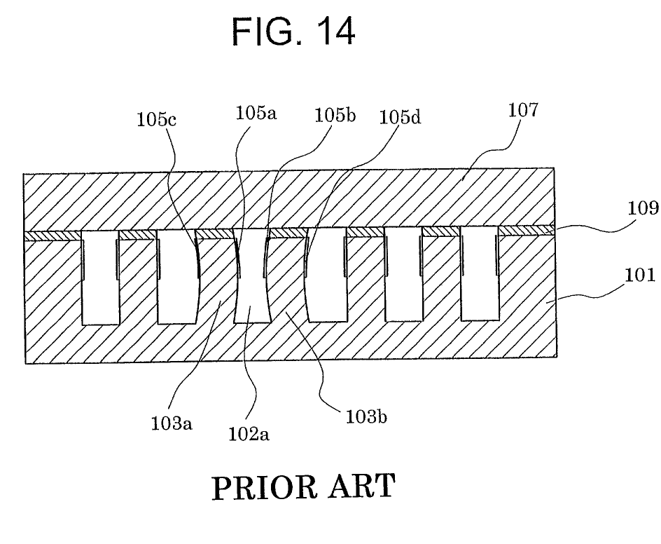

### DETAILED DESCRIPTION OF THE PREFERRED EMBODIMENTS

Hereinafter, the present invention will be described in detail with reference to embodiments.

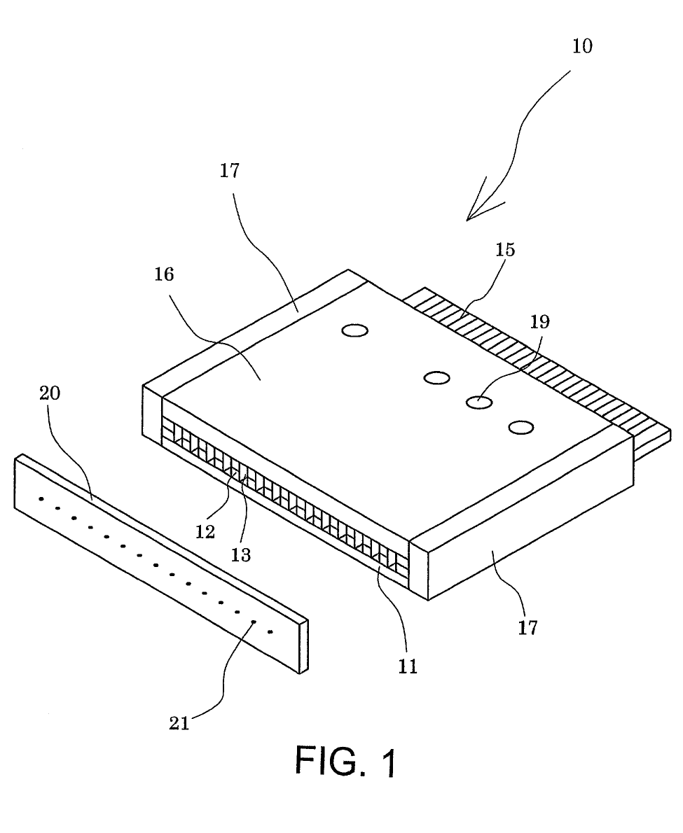

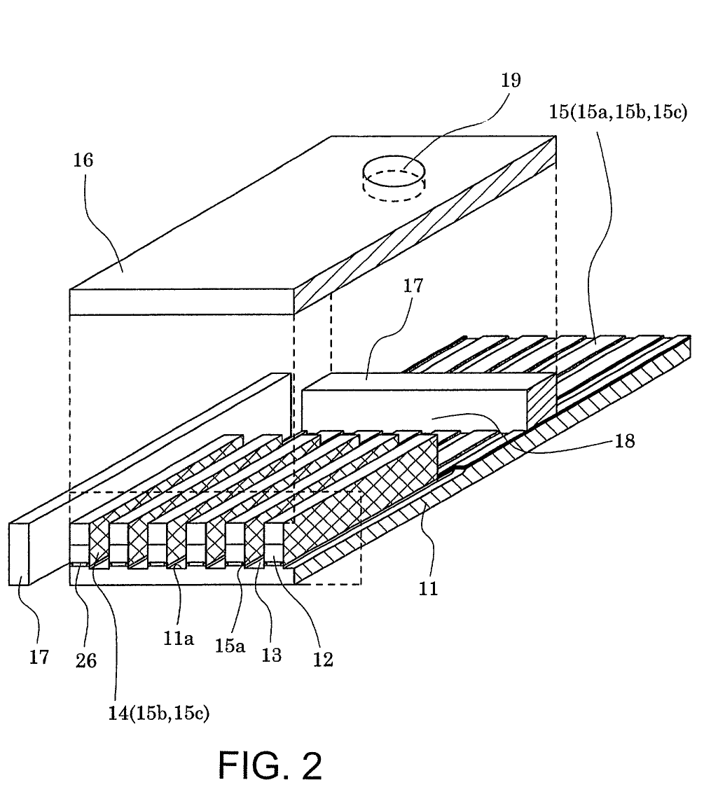

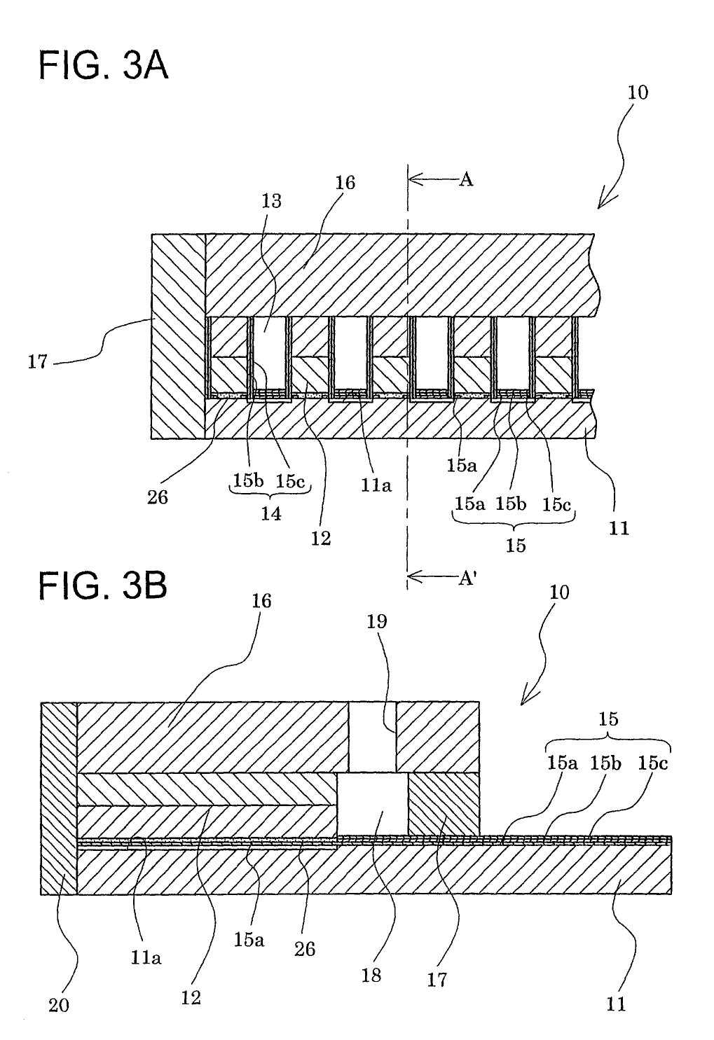

FIG. 1 is a perspective view indicating a head chip according to an embodiment of the present invention. FIG. 2 is a sectional/perspective view of the head chip. FIG.3A is a sectional view showing a chamber along a parallel-arranging direction, and FIG. 3B is a sectional view of the chamber, taken along a line A-A′ of FIG. 3A.

As indicated in the drawings, a plurality of partition walls 12 made of piezoelectric ceramics are arranged in a parallel manner with keeping a predetermined interval on a glass board 11 having a plate shape. A plurality of chambers 13 are defined by the partition walls 12.

Also, an electrode 14 used to apply a driving electric field is formed over an entire surface of each side surface of the partition wall 12 which constitutes an inner surface of each of these chambers 13.

Also, on the glass board 11, wiring lines 15 electrically conducted to the respective electrodes 14 are elongated up to outer sides of the respective partition walls 13 along the longitudinal direction. Further, in a region located opposite to the partition wall 12, the wiring lines 15 are provided in such a region along the longitudinal direction, which is located opposite to each of both edge portions of the partition wall 12 along the width direction. Then, while the side surfaces of the wiring lines 15 on the side of the chamber 13 are exposed, the wiring lines 15 are firmly made in contact with the electrode 14 on this exposed side surface. Thus, the electrode 14 can be electrically conducted to the wiring lines 15.

This wiring line 15 is constituted of an inorganic conductive film 15a provided on the lowermost layer, and at least one layer of a metal film formed on this inorganic conductive film 15a. In this embodiment, this metal film is constituted of two layers of metal films 15b and 15c.

Also, guide walls 17 made of plastic are fixed by an adhesive agent or the like on a position, that is located opposite to one end of each of the partition walls 12 in the longitudinal direction on the glass board 11, and both side surfaces of the glass board 11. An ink chamber 18 which is communicated to each of the chambers 13 is defined by both the guide wall 17 and the partition wall 12 on the glass board 11. This ink chamber 18 is sealed by a cover plate 16 made of a plate-shaped glass material, which is joined on the side opposite to the glass board 11 of the partition wall 12. It should be noted that an ink supply port 19 used to supply ink to the ink chamber 18 is formed in this cover plate 16 by using, for example, sandblasting.

Also, a nozzle plate 20 is jointed to an edge surface which is identical to an edge surface of the glass board 11 of the partition wall 12. A nozzle opening 21 is pierced in a position which is located opposite to each of the chambers 13 of this nozzle plate 20. This nozzle plate 20 may be manufactured by plastic, glass, or a polyimide film.

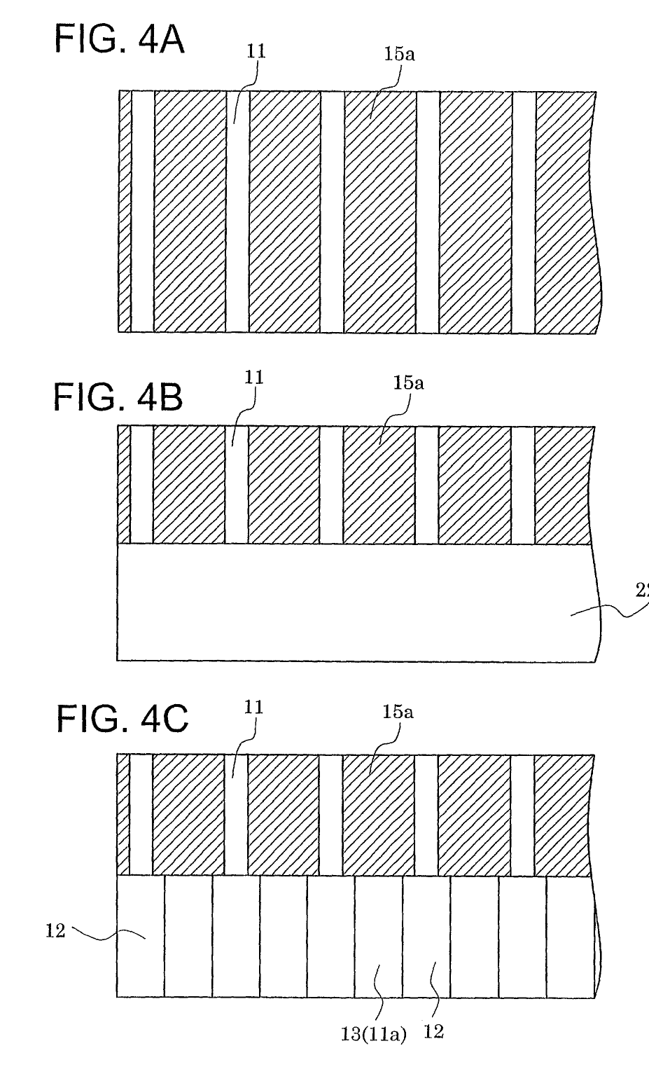

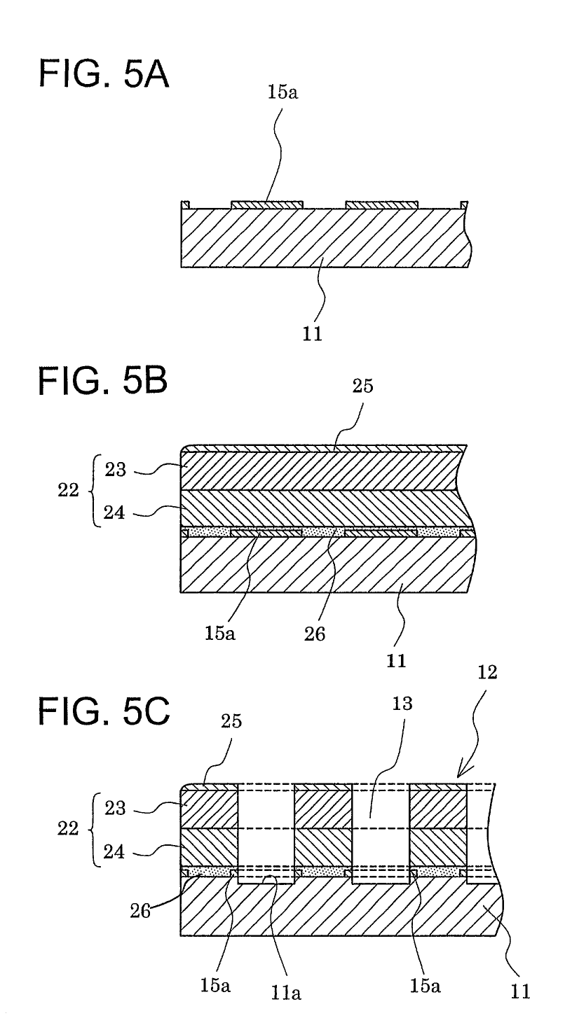

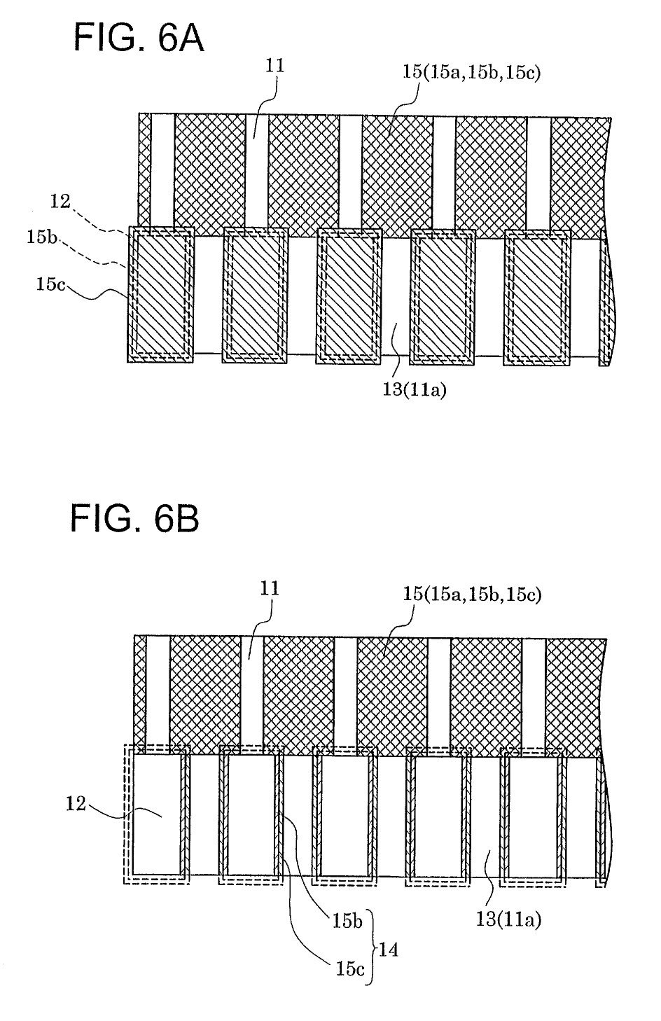

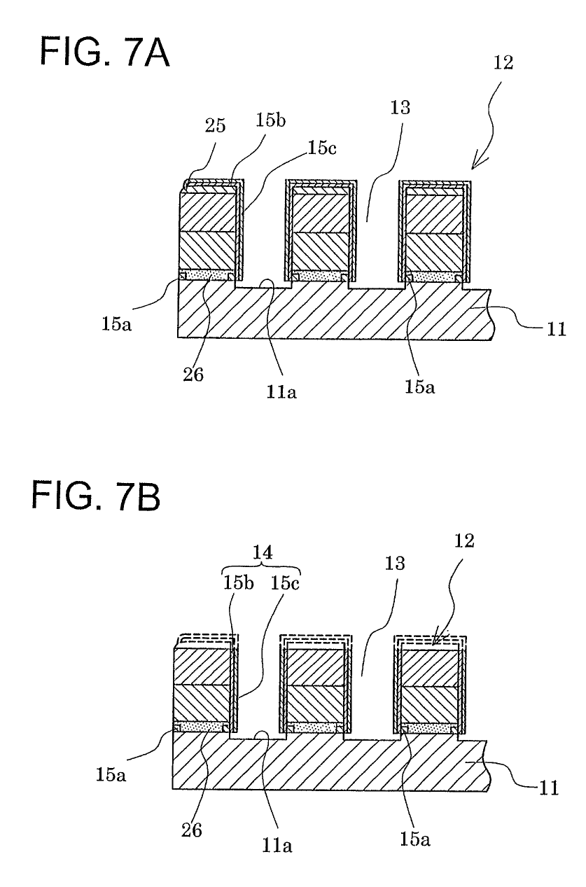

Now, a manufacturing step for such a head chip according to this embodiment will be described in detail. FIG. 4 and FIG. 6 are top views representing the manufacturing steps of the head chip, and FIG. 5 and FIG. 7 are sectional views showing the head chips at the respective manufacturing steps along the parallel-arranging direction of the chambers 13.

As shown in FIG.4A and FIG.5A, the inorganic conductive film 15a having a predetermined shape is formed on the plate-shaped glass board 11. Concretely speaking, after the inorganic conductive film 15a has been formed on the entire surface of the glass board 11, this formed inorganic conductive film 15a is patterned. Thus, the respective inorganic conductive films 15a are formed on such a region where the respective chambers 13 are formed on the glass board 11. The width of each of the inorganic conductive films 15a is made slightly wider than the width of each of the chambers 13.

In this case, as a material of the inorganic conductive film 15a, for instance, ITO (oxide made of indium and tin), SnO₂, ZnO or ATO (oxide made of antimony and tin) may be employed. In this embodiment, ITO is used.

If the film thickness of such an inorganic conductive film 15a is made excessively thick, the following fears may occur that when the partition wall 12 is adhered to the inorganic conductive film 15a at the below-mentioned step, insufficient adhesion readily occurs, and that when the partition wall 12 is driven, this partition wall 12 is moved and/or stripped. As a consequence, it is preferable that the film thickness of the inorganic conductive film 15a is made relatively thin, preferably made equal to or thinner than 3 μm.

It should also be noted that the method of forming this inorganic conductive film 15a is not specifically limited. For instance, after the inorganic conductive film 15a has been manufactured by a sputtering method, a coating method or the like, the manufactured inorganic conductive film may be patterned by employing a photolithographic method or the like.

Subsequently, as shown in FIG. 4B and FIG. 5B, a piezoelectric ceramic plate 22 is adhered on the inorganic conductive film 15a by using an adhesive agent 26 such that this piezoelectric ceramic plate 22 is aligned to one edge of the glass board 11.

It should also be noted that this piezoelectric ceramic plate 22 is formed such that two sheets of piezoelectric ceramic plates 23 and 24, the polarization directions of which are different from each other, are adhered to each other along the thickness direction in this embodiment. Also, surfaces other than the adhesive surface of this piezoelectric ceramic plate 22 are coated in advance by using resist 25 before being adhered. This is a process to remove an unnecessary electrode film in the below-mentioned manufacturing step. Alternatively, this resist 25 may be apparently formed after the adhesive process.

Subsequently, as shown in FIG. 4C and FIG. 5C, the piezoelectric ceramic plate 22 is cut into the respective partition walls 12, and also the chamber 13 is formed. In other words, the piezoelectric ceramic plate 22 is cut along the thickness direction so as to form the partition walls 12 such that grooves having predetermined widths, which will form the chambers 13, are formed in this piezoelectric ceramic plate 22 by using, for example, a disk-shape die cutter.

At this time, the inorganic conductive film 15a has to be cut in connection with the piezoelectric ceramic plate 22 in order that the inorganic conductive film 15a formed on the glass board 11 does not become conductive within the chamber 13. Therefore, in this embodiment, the inorganic conductive film 15a is firmly cut by removing a part of the glass board 11 in the thickness direction to form a concave portion 11a. Apparently, while the inorganic conductive film 15a is previously patterned, this inorganic conductive film 15a may be brought in to the cut-outcondition. Also, if the inorganic conductive film 15a is completely cut, the concave portion 11a may not be formed.

As previously explained, since the inorganic conductive film 15a is patterned with the width that is made slightly wider than the width of the chamber 13, when the partition wall 12 is formed, and also when the piezoelectric ceramic plate 22 is cut, the inorganic conductive film 15a will be left along the longitudinal direction between both the edge portions of the partition wall 12 in the width direction and the glass board 11, and the side surface of this remaining inorganic conductive film 15a is exposed.

It should be noted that this inorganic conductive film 15a is continued up to the outer side of the partition wall 12.

Subsequently, as shown in FIG. 6A and FIG. 7A, a starting catalyst containing palladium, platinum or the like is absorbed over the entire surfaces of both the partition wall 12 and,.the inorganic conductive film 15a, namely surfaces other than the surface of the glass board 11. Thereafter, the electrode 14 and both the metal film 15b made of nickel and the metal film 15c made of gold, which may constitute a portion of the wiring line 15, are successively formed by way of the selective electroless plating.

Such a wiring line 15, that is made of three layers, namely the inorganic conductive film 15a, the nickel metal film 15b, and the gold metal film 15c, is formed outside the partition wall 12 by this selective electroless plating. Also, both the metal films 15b and 15c formed over the entire surface of the partition wall 12 may be electrically conducted to the inorganic conductive film 15a formed between the partition wall 12 and the glass board 11 on the exposed side surfaces thereof.

Next, as shown in FIG. 6B and FIG. 7B, the resist 25, which is formed on both the upper surface of the partition wall 12 and the edge surfaces of the partition wall 12 along the longitudinal direction, and also unnecessary metal films 15b and 15c formed on the resist 25 are lifted off. As a result, such an electrode 14, which is not short-circuited on both the side surfaces of the partition wall 12 and which is constructed of two layers made from the nickel metal film 15b and the gold metal film 15c, is formed.

As previously explained, both the electrode films 15b and 15c which constitute the electrode 14 formed in this manner are electrically conducted with the inorganic conductive film 15a on the exposed side surfaces thereof. In other words, the electrode 14 is mutually and electrically conducted via the inorganic conductive film 15a to the wiring line 15.

Thereafter, as indicated in FIG. 1 to FIG. 3, the guide wall 17 made of plastic is fixed on the rear portion of each of the partition walls 12, and also both the edge surfaces of the glass board 11 along the parallel-arranging direction of the partition walls 12 by using the adhesive agent or the like, so that the ink chamber 18 is defined on the glass board 11. Then, the cover plate 16 is fixed by using the adhesive agent or the like on the side opposite to the glass board 11 of the partition wall 12, and also the nozzle plate 20 having a plate shape, in which the nozzle openings 21 are pierced, is fixed on the side edge surface of the partition wall 12 of the glass board 11 with respect to each of the chambers 13. Then, the outer shape of the resultant head chip is processed by using the die, and thus, a desirable head chip 10 may be manufactured.

As explained above, in the manufacturing method in accordance with this embodiment, the inorganic conductive film 15a is patterned on the glass board 11, and the selective electroless plating is performed on, this inorganic conductive film 15a. As a result, the wiring lines 15 can be readily manufactured, and also the head chip can be manufactured while improving the fitting characteristic between the glass board 11 and the wiring lines 15.

Also, since the electrode 14 can be formed at the same time when the wiring lines 15 are formed, the entire manufacturing steps can be made simpler, and further, the manufacturing cost can be reduced. Furthermore,the manufacturing cost can be reduced by using a large amount of low-cost glass.

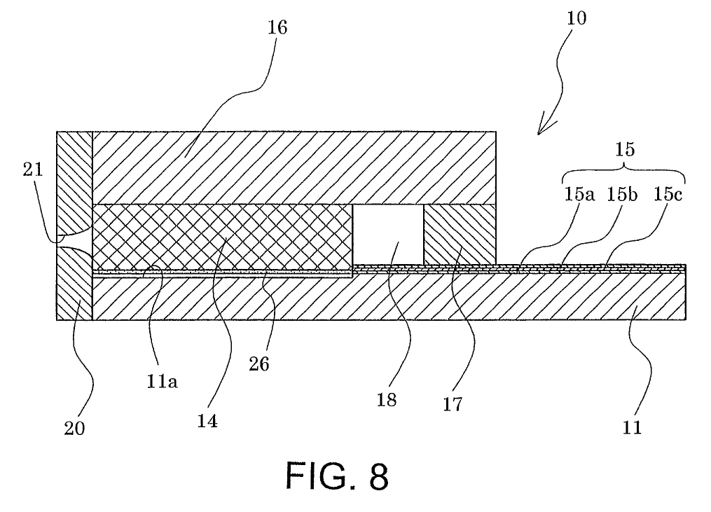

It should be noted that in this embodiment, the inorganic conductive film 15a elongated between the glass board 11 and the partition wall 12 is formed along the longitudinal direction of the partition wall 12. The present invention is not limited thereto if the inorganic conductive film 15a can be electrically conducted to the electrode 14 provided on the side surface of the partition wall 12. Only a portion of the inorganic conductive film 15a may be elongated along the longitudinal direction. For instance, as indicated in FIG. 8, the inorganic conductive film 15a is not elongated between the glass board 11 and the partition wall 12, but may be alternatively provided so as to be in contact with the edge surface of the partition wall 12. In any cases, it is necessary that the electrode 14 is surely and electrically conducted with the wiring lines 15. It should be noted that FIG. 8 is a sectional view showing the chamber 13 along the longitudinal direction, in which both the metal films .15b and 15c which constitute a portion of the wiring lines 15, are continued to the electrode 14 at the edge portions along the longitudinal direction thereof.

Although there is no limitation on the way how to form wiring lines used to drive the head chip 10 manufactured in this manner, one example thereof will now be explained.

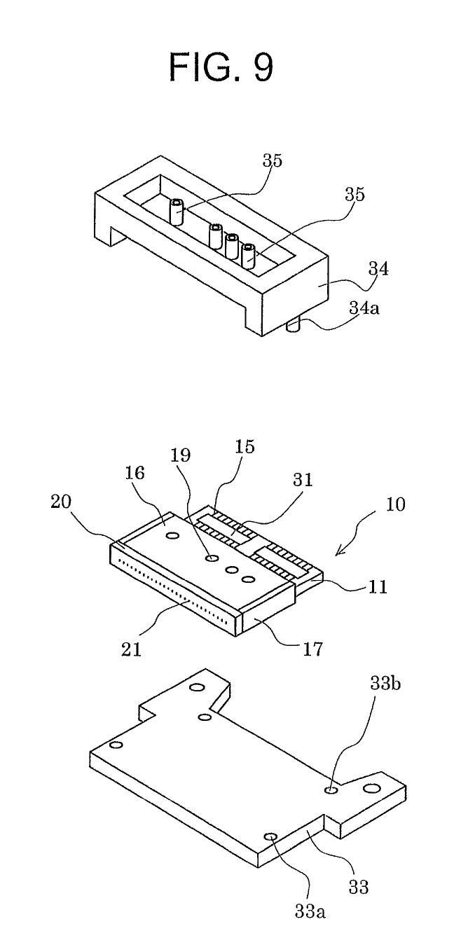

FIG. 9 is an exploded perspective view indicating a head chip unit on which the above-explained head chip 10 is mounted.

As illustrated in FIG. 9, a driver circuit 31 such as an integrated circuit for driving the head chip 10 is directly connected to the wiring line 15, and this driver circuit 31 is mounted on the glass board 11 of the head chip 10. Also, a base plate 33 made of aluminum is assembled on the side of the glass board 11, and a head cover 34 is assembled on the side of the cover plate 16 in the head chip 10. The base plate 33 is fixed to the head cover 34 such that an engaging shaft 34a of the head cover 34 is engaged with an engaging hole 33a of the base plate 33, and the head chip 10 is sandwiched by both the base plate 33 and the head cover 34. An ink conducting path 35 is formed on the head cover 34, and this ink conducting path 35 is communicated with each of the ink supply ports 19 of the cover plate 16.

Also, such ahead chip unit 40 may be assembled with, for example, a tank holder, which detachably holds the ink cartridge, to be used.

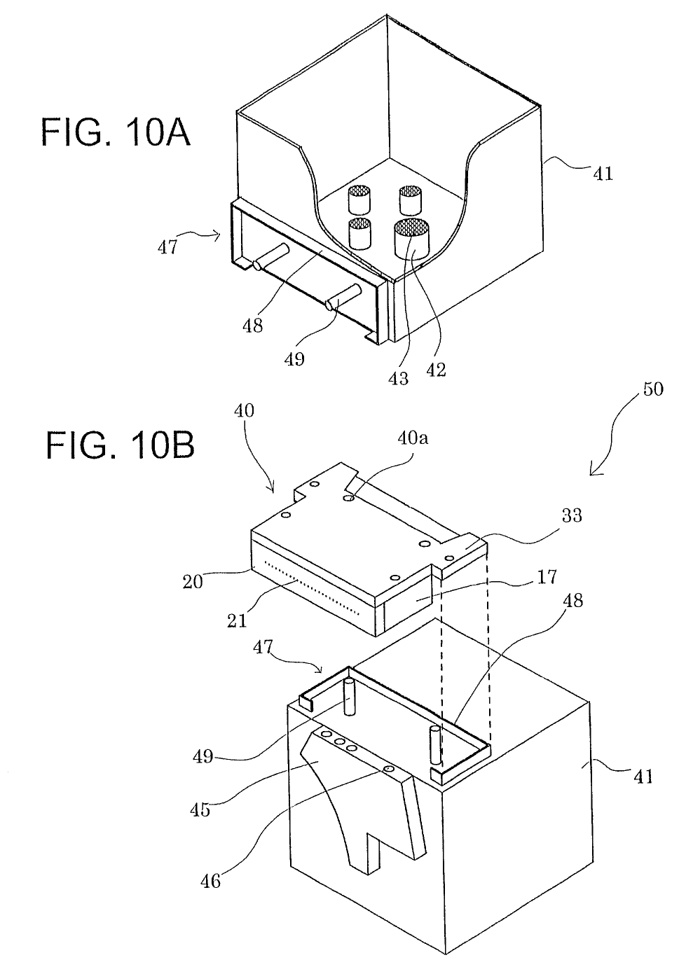

FIG. 10A shows an example of such a tank holder. FIG. 10B shows the tank holder 41 and the head chip unit 40 which is assembled with the tank holder 41. The tank holder 41 shown in FIG. 10 is formed to have substantially a box shape whose one surface is opened, and an ink cartridge (not shown) may be detachably held. A coupling portion 42 is provided on an upper surface of a bottom wall, and is coupled to the ink supply port 19 corresponding to an opening portion formed in the bottom portion of the ink cartridge. A plurality of the coupling portions 42 are provided with respect to each of color ink, for instance, black (B) ink, yellow (Y) ink, magenta (M) ink, and cyan (C) ink. An ink flow path (not shown) is formed inside the coupling portion 42, and a filter 43 is provided at a tip portion of the coupling portion 42 which constitutes an opening of this ink flow path. The ink flow path formed inside the coupling portion 42 is communicated to the rear surface of the bottom wall. The respective ink flow paths are communicated to a head coupling port 46 which is opened in the partition wall of a flow path board 45 via an ink flow path (not shown) which is provided within the flow path board 45 provided on the side of the rear surface of the tank holder 41. This head coupling port 46 is opened on the side of the side surface of the tank holder 41, and a head chip unit holding portion 47 which holds the above-described head chip unit 40 is provided on the bottom portion of this partition wall. In the head chip unit holding portion 47, there are provided a surrounding wall 48 and an engaging shaft 49. The surrounding wall 48 surrounds the driver circuit 31 provided on the glass board 11, and is formed into substantially a U-shape and positioned in an upright manner. The engaging shaft 49 is engaged with an engaging hole 33b formed in the base plate 33 of the head chip unit 40 provided inside the surrounding wall 48.

As a consequence, the head chip unit 40 is mounted on this head chip unit holding portion 47, so that a head unit 50 can be completed. At this time, the ink conducting path 35 formed in the head cover 34 is coupled to the head coupling port 46 of the flow path board 45. As a result, the ink which is conducted from the ink cartridge via the coupling portion 42 of the tank holder 41 is conducted via the ink flow path formed in the flow path board 45 into the ink conducting path 35 of the head chip unit 40, so that this ink is filled into both the ink chamber 18 and the chamber 13.

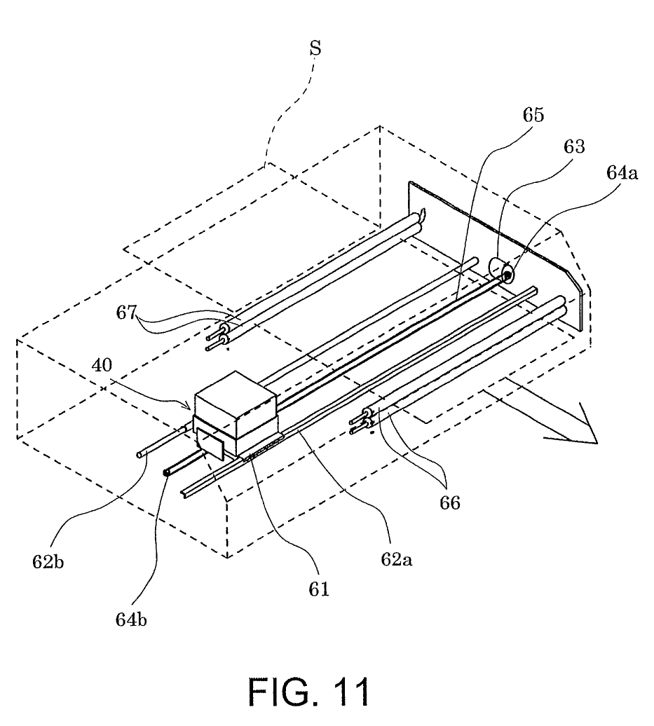

Such a head unit 50 is mounted on, for instance, a carriage of an ink-jet type recording apparatus so as to be used. FIG. 11 schematically shows an example of this use mode of the head unit 50.

As shown in FIG. 11, a carriage 61 is movably mounted on one pair of guiderails 62a and 62b along an shaft direction. This carriage 61 is transported by way of a timing belt 65 which is suspended between a pulley 64a, that is provided on one end side of the guide rail 62, and is coupled to a carriage driving motor 63, and another pulley 64b that is provided on the other side of this guide rail 62. A pair of transfer rollers 66 and 67 are provided along the guide rails 62a and 62b on both sides in a direction perpendicular to the transport direction of the carriage 61. The set ransferrollers 66 and 67 are used to transport a recording medium “S” located below the carriage 61 along a direction perpendicular to the transport direction of this carriage 61.

The above-explained head unit 50 is mounted on the carriage 61, and the above-explained ink cartridge may be detachably mounted on this head unit 50.

In accordance with such an ink-jet type recording apparatus, while the recording medium “S” is fed, the carriage 61 is scanned along the direction perpendicular to this medium feeding direction, so that both a character and an image can be recorded on this recording medium “S” by the head chip.

While the present invention has been described with the embodiment, the present invention is not limited to such a construction thereof.

As previously described, in accordance with the present invention, both the upper board and the lower board, which sandwich the partition wall made of the piezoelectric ceramic, are formed by the dielectric material, and also, the inorganic conductive film is employed as the lowermost layer of the wiring lines which are electrically conducted to the electrode. Thus, the manufacturing steps of the wiring lines can be made simple and also can be manufactured in low cost. Also, the fitting characteristic between the wiring lines and the boards can be improved.

What is claimed is:

1. A method of manufacturing a head chip, in which partition walls made of piezoelectric ceramic are arranged in a predetermined interval between a first upper board and a second lower board, which are made of a dielectric material; chambers are defined among the respective partition walls; and a wiring line is provided on a surface of any one of the first board and the second board, and is electrically conducted to an electrode formed on a side surface of the partition wall, and also is elongated up to an outer side of an edge portion of the partition wall along a longitudinal direction; the manufacturing method characterized by comprising:
a step in which the electrode and a metal film which constitutes a portion of the wiring line are formed by way of selective electroless plating, and these electrode and wiring line are electrically conducted to each other.

2. A manufacturing method of a head chip as claimed in claim 1 characterized in that:
at least in a region corresponding to the chamber, an inorganic conductive film is formed on a portion located opposite to both edge portions of the partition wall in a width direction such that one side surface of the inorganic conductive film is exposed along a longitudinal direction of the partition wall; and
the electrode is electrically conducted to at least the one side surface of the inorganic conductive film, which is exposed.

3. A manufacturing method of a head chip as claimed in claim 2 characterized in that:
the electrode is formed by way of selective electroless plating such that the electrode is made in contact with the exposed one side surface of the inorganic conductive film to thereby be electrically conducted to the inorganic conductive film; and also the metal film is formed on the inorganic conductive film of the outer side of the partition wall along the longitudinal direction, whereby the electrode is electrically and mutually conducted via the inorganic conductive film to the metal film.

4. A manufacturing method of a head chip as claimed in any one of claims 1 to 3, characterized by further comprising, prior to the step of forming the electrode and the metal film:
a step of forming an inorganic conductive film having a predetermined shape, which constitutes a portion of the wiring line, on any one of the first board and the second board; and
a step of providing the partition wall on the one board where the inorganic conductive film is formed.

5. A manufacturing method of a head chip as claimed in any one of claims 1 to 3 characterized in that:
the step for forming the partition wall includes:
a step of joining a piezoelectric ceramic plate corresponding to a block which constitutes a plurality of partition walls on any one of the first board and the second board; and
a step of cutting the piezoelectric ceramic plate to form a plurality of partition walls.

6. A manufacturing method of a head chip as claimed in claim 5 characterized in that:
the piezoelectric ceramic plate is jointed on the one board where the inorganic conductive film is formed, and both the piezoelectric ceramic plate and the one board located up to a portion of the one board in the thickness direction are removed, whereby the plurality of portion walls are formed.

7. A manufacturing method of a head chip as Claimed in any one of claims 1 to 3 characterized in that:
the dielectric material is glass.

8. A manufacturing method of a head chip as claimed in any one of claims 1 to 3 characterized in that:
the inorganic conductive film is made of at least one sort of material selected from the group consisting of ITO, Sn, O₂, ZnO, and ATO.

9. A manufacturing method of a head chip as claimed in any one of claims 1 to 3 characterized in that:
a thickness of the inorganic conductive film is set to be equal to or thinner than 3 μm.

10. A manufacturing method of a head chip as claimed in any one of claims 1 to 3 characterized in that:
the partition wall is formed by adhering two members, which e different polarization, to each other.

11. A manufacturing method of a head chip as claimed in any of claims 1 to 3 characterized in that:
both the electrode and the metal film are made of at least material selected from nickel and gold.

12. A manufacturing method of a head chip as claimed in any of claims 1 to 3, characterized by further comprising a step providing a nozzle plate on one opening end of the chamber along a longitudinal direction of the partition wall, the nozzle plate having nozzle openings which are communicated to the respective members.

13. A manufacturing method of a head chip as claimed in claim characterized in that:
the nozzle plate is made of a dielectric material.
